(19) United States
(12) Patent Application Publication
(10) Pub. No.: US 2006/0054210 A1
(43) Pub. Date: Mar. 16, 2006

(54) Photovoltaic module with an electronic device in the laminated stack

(76) Inventors: Bernard Proisy, Solaize (FR); Christophe Dugue, Cessieu (FR); Michel Laporte, Montceau (FR); Nam Le Quang, L'Isle D'Abeau (FR)

Correspondence Address: BORDEN LADNER GERVAIS LLP, 1100-100 QUEEN ST, OTTAWA, ON, K1P 1J9, CA

(21) Appl. No.: 11/010,319

(22) Filed: Dec. 14, 2004

(30) Foreign Application Priority Data
Dec. 15, 2003 (FR) 03 51060

(51) Int. Cl. H01L 25/00

(52) U.S. Cl. 136/244; 136/251

(57) ABSTRACT

A photovoltaic module including one or more photovoltaic cells connected in series and located inside a laminated stack of glass and polymer, together with an electronic protection device, e.g. a bypass diode, which is arranged to bypass the electric current passing through at least one photovoltaic cell. The electronic protection device, which is a semiconductor circuit, is itself disposed inside the laminated stack. The semiconductor circuit is electrically connected to at least one flat metal ribbon disposed in the laminated stack for the purpose of dissipating the heat energy given off by the semiconductor circuit.

### FIELD OF THE INVENTION

The invention relates to a photovoltaic module which serves in particular for transforming solar energy into electrical energy.

### BACKGROUND OF THE INVENTION

Such photovoltaic modules are presently designed to deliver electrical power in the range 12 watts (W) to 230 W. They are used in numerous terrestrial applications for providing direct current (DC) or alternating current (AC). For example, they are used in sites that are isolated or that are connected to the power supply distribution network:

in public utility power supply networks;

by individuals: lighting, radio, television (TV), small household appliances;

for public lighting: advertising panels, bus shelters;

for rural electrification;

for pumping;

for telecommunications: infrastructure, relays in the global system for mobile telecommunications (GSM), isolated subscriber equipment;

for signaling: roadside, at sea, radio, TV.

In general, a photovoltaic module comprises N photovoltaic cells, e.g. thirty-six cells, collected in series and connected to one another by flat ribbons of tinned copper. More particularly, the photovoltaic cells are single-junction photovoltaic cells made on the basis of poly-crystalline silicon that is P-doped using boron when melting the silicon, and N-doped with phosphorus on their illuminated surface. Such cells are put into place in a laminated stack. The laminated stack may be constituted by ethyl vinyl acetate (EVA) coating the photovoltaic cells in order to protect the silicon from which the cells are made from oxidation and from moisture, said photovoltaic cells also being interleaved between a plate of quenched glass and a polymer sheet, e.g. made of Tedlar® which is a fluorinated polyvinyl manufactured by the supplier DuPont. That structure enables the photovoltaic module to withstand the most severe atmospheric and environmental conditions, such as those that are to be found in the tropics, at the Poles, or at sea.

The current Im delivered by the photovoltaic module is equal to the current Ic produced by each of the photovoltaic cells in the module. The current Ic depends mainly on illumination, and on the physical characteristics of the cells such as their size and the quality of the silicon from which they are made. The voltage Vm delivered by the module is the sum of the voltages Vc delivered by each of the photovoltaic cells in the module when subjected to lighting, and it is given by the relationship:

$$Vm = {\sum }_{i = 1} to {}_{N}^{}{Vc}{}_{i}^{}$$

When one of the photovoltaic cells of the module is shaded, i.e. when it is not receiving light either because of damage or because it has been covered by an opaque material, e.g. a leaf, then the cell no longer delivers any electrical energy. However, it can increase in resistance and receive electrical energy produced by the other cells with which it is connected in series. As a result the voltage Vo across the terminals of the shaded cell then becomes reversed and can reach a voltage that is equivalent to the sum of the voltages across all the other cells in the module, with this equivalent voltage being calculated by the following relationship:

$$Vo = {\sum }_{i = 1} to {}_{N}^{}{Vc}{}_{i}^{}$$

The power Wo received by the shaded cell that can reach the maximum power produced by all the other cells in the module, such that the shaded cell heats up, which can lead to it being destroyed, and also to damage to the laminated stack and to the module. This power received by the shaded cell is expressed by the following relationship:
Vo=Im*Vo

To reduce the heating of shaded cells and the loss of energy caused thereby in a photovoltaic module, it is the practice to use bypass diodes that are connected in parallel with some number of photovoltaic cells connected in series, e.g. eighteen. A module can thus contain a plurality of bypass diodes connected in parallel with respective ones of several groups of cells. As a result, a shaded cell is protected since the bypass diode starts conducting the current, thereby limiting the power received by the shaded cell. The shaded cell therefore heats up very little, but instead the bypass diode that heats up. The power dissipated by the diode is equal to the product of the DC voltage across the diode multiplied by the current flowing through it, where said current is the difference between the current flowing through the external circuit and the current flowing through the shaded cell. Furthermore, the shaded cell receives only the power delivered by the other photovoltaic cells in the same group of cells protected by the same bypass diode in the module, thereby limiting the extent to which it heats up and reducing the loss of energy from the module. The smaller the number of cells in a group of cells that is protected by a bypass diode, the greater the extent to which heating is limited and energy losses are small.

In known photovoltaic modules, bypass diodes are located in a junction box that is separate from the laminated structure of the module. The heat dissipated by the bypass diodes in junction boxes may not be sufficient. In addition, application of the new qualification standard IEC61215 Ed.2, which will come into force very shortly, considerably stiffness the test criteria that protection bypass diodes must satisfy. The stiffer test criteria lead to an increase in the amount of the heat dissipated by bypass diodes. The temperature of the bypass diodes placed in the junction box then rises to values that are well in excess of the authorized limit values.

In the present state of the art it is not possible to satisfy the new standard without using power bypass diodes or without installing radiators on the bypass diodes, as disclosed in U.S. Pat. No. 6,225,793, thereby considerably increasing the cost of the module.

In addition, putting other semiconductor circuits for monitoring and controlling the module, e.g. circuits of the metal-oxide-silicon field effect transistor (MOSFET), thyristor, or gate turn-off thyristor (GTO) type in the junction boxes increases the complexity of the cabling between a junction box and the photovoltaic cells.

In document WO99/62125, the bypass diodes are mounted in the laminated stack on the photovoltaic cells so as the photovoltaic cells dissipate the heat provided by the bypass diode but this dissipation is not enough.

### SUMMARY OF THE INVENTION

The object of the invention is to remedy the drawbacks set out above by proposing a photovoltaic module in which the heat dissipation of the bypass diodes is improved at lower cost.

To this end, the invention provides a photovoltaic module comprising one or more photovoltaic cells connected in series and disposed inside a laminated stack of glass and polymer, and an electronic protection device, e.g. a bypass diode, arranged to bypass the electric current passing through at least one photovoltaic cell, the electronic protection device being a semiconductor circuit that is disposed inside the laminated stack, wherein the semiconductor circuit is electrically connected to the cells of the module via at least one flat metal ribbon disposed in the laminated stack in order to dissipate the heat energy given off by the semiconductor circuit.

This arrangement of the photovoltaic cells and of the bypass diodes in a photovoltaic module enables some of the cabling to be omitted. There is no longer any need for the flat copper ribbons to extend outside the laminated stack in order to protect the photovoltaic module with bypass diodes. The flat metal ribbons serve to improve the heat dissipation of the semiconductor circuit by establishing a large heat exchange area with the surrounding elements and also with the outside of the module.

In a preferred embodiment of the invention, the semiconductor circuit is connected to the photovoltaic cells via two flat copper ribbons.

In another preferred embodiment of the invention, the semiconductor circuit is an electronic chip soldered onto a photovoltaic cell.

In another preferred embodiment of the invention, each photovoltaic cell is inserted between a glass plate and a polymer layer, the semiconductor protection circuit being disposed between a cell and the polymer layer. The bypass diodes can then dissipate heat energy via the polymer layer and via the photovoltaic cell which presents good thermal conductivity.

In another preferred embodiment, the semiconductor circuit is disposed between two adjacent photovoltaic cells.

In another preferred embodiment, the semiconductor circuit comprises a poly-crystalline medium. The bypass diodes do not need to be of very high performance and can very well be made at moderate cost using a poly-crystalline medium.

In another preferred embodiment of the invention, the semiconductor circuit is mounted on a metal plate possessing good thermal conductivity, said plate serving as a radiator for dissipating heat energy.

In another preferred embodiment of the invention, the semiconductor circuit is integrated in the photovoltaic cell, thereby eliminating all cabling between the cells for module protection purposes.

In another preferred embodiment of the invention, each photovoltaic cell is provided with a respective protective semiconductor circuit. Locating a parallel bypass diode on each photovoltaic cell limits problems associated with shaded cells, since the shaded cell and the corresponding bypass diodes are then isolated and do not dissipate the power supplied by the other cells. In addition, there is no longer any need to provide cabling to enable a plurality of cells to be connected in parallel with a diode.

In another preferred embodiment of the invention, the photovoltaic module further comprises monitoring and/or control circuits for the photovoltaic cells, and in which the monitoring and/or control circuits are semiconductor circuits disposed inside the laminated stack. The semiconductor circuits for monitoring and/or control can be included in the laminated stack in order to protect the photovoltaic modules against theft or to manage access rights to the current produced.

In another preferred embodiment of the invention, the monitoring and/or control circuits are semiconductor circuits of the thyristor, MOSFET, or GTO type.

### BRIEF DESCRIPTION OF THE DRAWINGS

Various embodiments of a photovoltaic module in accordance with-the invention are described below in greater detail and are shown in the accompanying drawings.

FIG. 1 is a diagram of a laminated stack of a photovoltaic module of the invention.

FIG. 2 is a highly diagrammatic cross-section view of a portion of a laminated stack of a photovoltaic module of the invention.

FIG. 3 is a highly diagrammatic view of a semiconductor circuit for protecting a photovoltaic module of the invention.

FIG. 4 is a highly diagrammatic view of a semiconductor protection circuit arranged on a plate of a photovoltaic module of the invention.

FIG. 5 is a highly diagrammatic view of a semiconductor circuit for monitoring and/or controlling a photovoltaic module of the invention.

FIG. 6 is a highly diagrammatic view of the rear face of a photovoltaic module of the invention.

FIG. 7 is a highly diagrammatic view of two photovoltaic cells connected in series and protected individually by respective semiconductor circuits in a photovoltaic module of the invention.

FIG. 8 is a highly diagrammatic view of a semiconductor circuit integrated in the rear face of a photovoltaic cell in a photovoltaic module of the invention.

### DETAILED DESCRIPTION

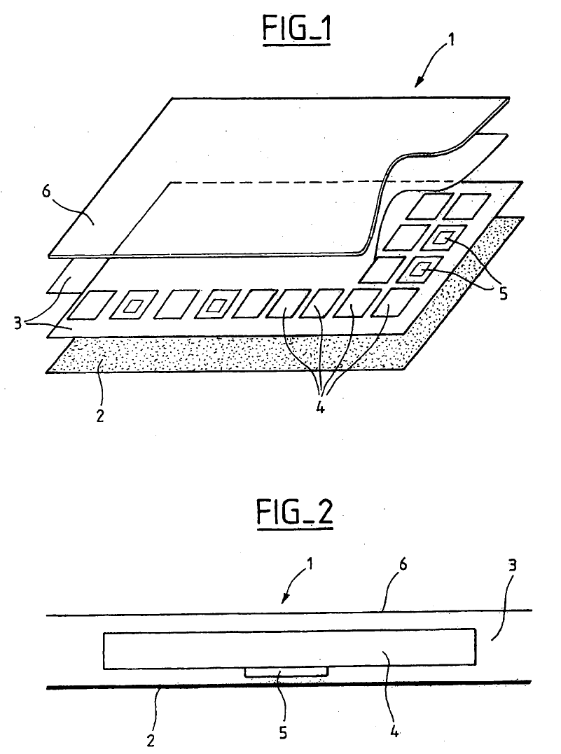

FIG. 1 is a diagram showing a laminated stack of a photovoltaic module 1 of the invention presenting a plurality of parallel layers stacked one on another. The back of the photovoltaic module 1 is formed by a layer of strong polymer, e.g. a sheet of Tedlar®, having deposited thereon an encapsulating polymer 3, e.g. EVA. Inside the encapsulated polymer there are arranged photovoltaic cells 4 in a common plane and ordered in a grid with their rear faces facing towards the layer 2, together with semiconductor circuits 5 placed under some of the photovoltaic cells 4. Finally, the encapsulating polymer 3 has a plate of glass 6 placed thereon to form the front of the photovoltaic module.

For the purpose of securing the photovoltaic cells 4 and the semiconductor circuits 5, the encapsulating polymer 3 can be cured in a vacuum and at a temperature of about 150° C. for EVA. The layer 2 of strong polymer then provides sealing and protection against mechanical damage to the back of the module, while minimizing its weight.

FIG. 2 shows the disposition of a flat semiconductor circuit 5 in the laminated stack of the invention. The semiconductor circuit 5 is in the encapsulated polymer 3, very close to the layer 2 of strong polymer.

The semiconductor circuit 5 which may be a protective semiconductor circuit (a bypass diode) can conduct current when protecting a shaded cell. It provides a bypass for the current flowing in the external circuit, which current can no longer flow through the shaded cell. The semiconductor circuit then receives the power, heats up, and dissipates thermal energy. Thermal dissipation is made easier by the photovoltaic cell 4 and the glass plate 6, since they present good thermal conductivity and act as a radiator. The thermal energy from the semiconductor circuit 5 is dissipated in the photovoltaic cell 4 which exchanges this thermal energy over its entire area with the encapsulating polymer 3 and the glass plate 6. In addition, the encapsulated polymer 3 and the polymer layer 2 also withstand easily the dissipation of heat from the semiconductor circuit 5. The semiconductor circuit 5 placed in the laminated stack of the invention thus heats up much less than would a similar semiconductor circuit if placed in a junction box.

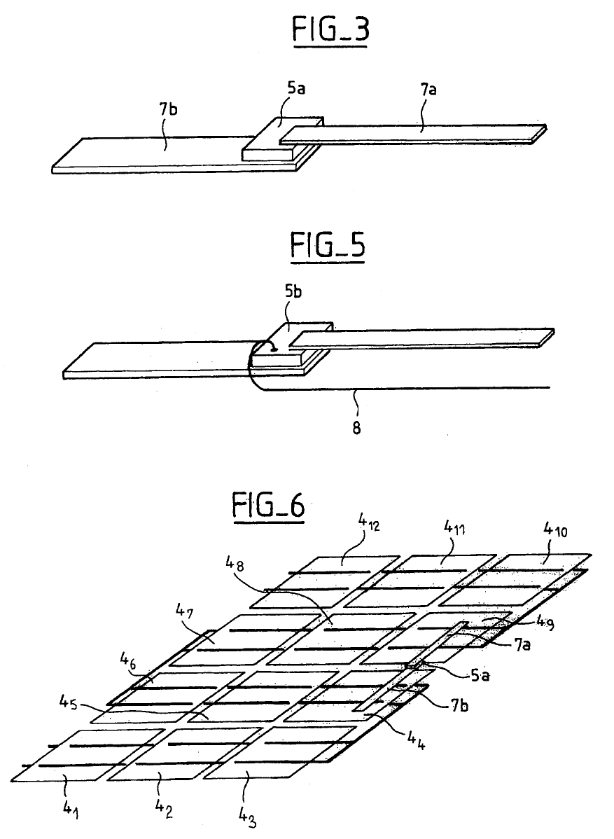

FIG. 3 shows a flat protective semiconductor circuit 5a (electronic chip) which constitutes a bypass diode serving to protect the photovoltaic module against shaded photovoltaic cells heating up. Two flat metal ribbons 7a and 7b, e.g. made of tinned copper, or made of materials that present very good thermal and electrical conductivity, are connected (soldered) to the input and the output of the bypass diode 5a. A copper ribbon 7a having a thickness of 220 micrometers (μm) and a width of 3 millimeters (mm) constitutes the anode and is connected to a photovoltaic cell (not shown) that presents a potential that is higher than the potential of the cell being protected. A copper ribbon 7b having thickness of 220 μm, and width of 5 mm, constitutes the cathode and is connected to another photovoltaic cell (not shown) presenting a potential lower than that connected to the anode. The ribbons 7a and 7b are of different widths in order to avoid making connections the wrong way around. When ribbons or cables cross over one another, they are insulated from one another by pieces or films of insulation, e.g. made of EVA-Tedlar.

The two flat copper ribbons 7a, 7b placed in the laminated stack have a very large area of contact with the bypass diode 5a and also very good thermal conductivity. They thus improve the dissipation of heat from the bypass diode. Heat from the diode is transferred to the ribbons 7a and 7b which, because of their wide flat shape, offer a very large area for exchanging heat energy with the surrounding elements such as the photovoltaic cells 4 to which they are connected, the encapsulating polymer 3, or the layer of strong polymer 2. This improved diffusion and distribution of heat improves the dissipaton of the heat from the semiconductor circuit 5.

The flat shape of the ribbons 7a and 7b also makes them easier to insert and integrate in the laminated stack of the module, which needs to remain as flat as possible.

The diode may also be connected directly between a photovoltaic cell and a flat copper ribbon. In which case it dissipates its heat energy in the cell and in the copper ribbon.

Laboratory tests have shown that the rise in the temperature of a bypass diode arranged in accordance with the invention is about 55% smaller than the prior art temperature rise. The tests were carried out in an environment at 75° C., and consisted in applying to the bypass diode a current equivalent to 1.25 times the maximum operating current of the module 1, and in measuring its temperature. The measured temperature was then compared with a limiting utilization temperature for the component and for the materials situated in its vicinity, as set by a qualification standard for validating the use of said bypass diode with said maximum current Given the present state of the art, when the new standard IEC613215 Ed.2 comes into force, it will become impossible to exceed a maximum current of 6 amps (A), whereas bypass diodes are presently required that are capable of operating, for example, with a maximum current of 10 A in order to protect photovoltaic cells having dimensions of 150 mm by 150 mm. The bypass diodes 5 arranged in the laminated stack of the invention satisfy the electrical and thermal technical characteristics of the new standard and make it possible to reach maximum currents of 15 A, thereby also satisfying present needs.

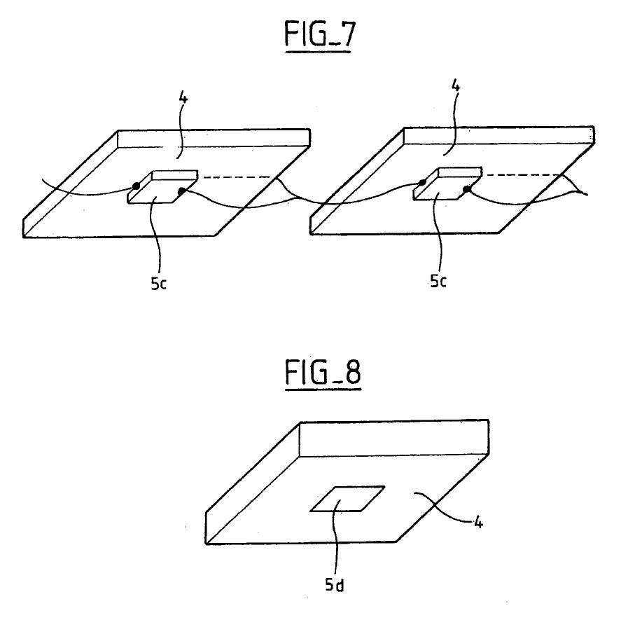

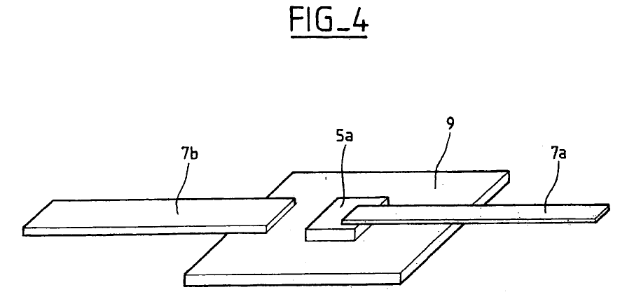

FIG. 4 shows a protective semiconductor circuit 5a arranged on a fine metal plate 9 made of a very good conductor of electricity and of heat, e.g. made of copper. The input or the output of the bypass diode 5a is soldered to the copper plate 9 which serves as a connection for one of the flat copper ribbons 7b. The other terminal of the diode is connected directly to another copper ribbon 7a.

The copper plate 9 serves as a radiator and enables the dissipation of heat from the bypass diode 5 to be further improved by increasing the area of heat exchange with the surrounding elements and also with the outside of the photovoltaic module 1.

In FIG. 5, there can be seen a semiconductor circuit 5b for monitoring and/or control purposes that presents a wire, optical, or electromagnetic connection 8 with the outside of the module. By way of example, the semiconductor circuit 5b is a thyristor, a MOSFET, or a GTO. The user of the module controls and monitors operation of the photovoltaic module via one or more semiconductors such as 5b, which are located in the laminated stack of the module. This arrangement enables the photovoltaic module to be protected against theft. In order to reach the semiconductor monitoring and/or control circuit 5b, which can be used as a switch or a circuit disconnector, it is necessary to open up the laminated stack of the module, and that operation is difficult. The monitoring and/or control semiconductor circuit 5b also makes it possible to provide effective control over access rights to the electricity produced when the photovoltaic module is operated on a rental basis.

FIG. 6 shows the rear of a photovoltaic module and shows an arrangement of twelve photovoltaic cells 4₁, 4₂, 4₃, 4₄, . . . , 4₁₂ connected in series. The rear face of each photovoltaic cell is electrically connected to the front face of the following photovoltaic cell. Between the rear face of the cell 4₄ and the rear face of the cell 4₉ there is connected a protective semiconductor circuit such as 5a in FIG. 3 by respective copper ribbons 7b and 7a. The semiconductor circuit 5a is then connected in parallel with the groups of cells comprising the photovoltaic cells 4₅-4₉. The semiconductor circuit 5a then enables protection to be provided for the photovoltaic cells 4₅-4₉ of the photovoltaic module.

Since the semiconductor circuit 5a is placed in the laminated stack of the module, there is no longer any need for certain cables to leave the laminated stack of the module. This reduces the length of the cables and thus their cost, and simplifies cabling and thus the operation of putting the cables into place, since fewer cables need to cross one another.

From FIG. 6, it is apparent that the electrical connections between photovoltaic cells belonging to different rows such as the connection between cell 43 and cell 44, have portions which extend beyond the lateral edge of the cells. One can arrange a photovoltaic module in which that portions of electrical connections are folded near the edge of the cells on the rear face of the module in order to reduce the size of the photovoltaic module. An insulator film, for example in EVA-Tedlar, enables to obviate electrical connection between connections and between connections and cells.

In the invention, each cell of the module 1 can be provided with a bypass diode 5c, as shown in FIG. 7. Thus, each cell is protected independently of the others against the overheating due to cells being shaded. This makes it possible to provide better protection for the photovoltaic module and avoids energy losses from the module by overheating any one cell or semiconductor. If a cell is shaded, current will flow via the bypass diode connected in parallel but very little energy will be consumed. The power received by the semiconductor 5cwill remain small, thereby avoiding damage to the cell and thus damage to the module.

In addition, no cabling between the various cells is needed to provide the module with protection, thereby further reducing cabling density.

The bypass diodes 5c needed for protecting the photovoltaic modules do not need to present very good performance (low reverse voltage and low leakage current are acceptable). Thus, it suffices to use protective semiconductor circuits 5c that are made on a poly-crystalline medium, of the same type as the medium used for making the photovoltaic cells 4. These semiconductor circuits 5c are of lower quality than electronic chips, but they are also much less expensive and can easily be fabricated by the manufacturer of the photovoltaic cells. It is therefore possible, while using poly-crystalline semiconductor circuits 5c, to implement one semiconductor circuit 5c per photovoltaic cell 4 at reasonable cost.

FIG. 7 shows that the semiconductor circuit 5c is soldered directly onto the rear face of the photovoltaic cell 4. This embodiment serves to eliminate even more cables.

A semiconductor circuit 5c can be soldered onto each photovoltaic cell 4 on an industrial scale in automatic manner by cold soldering or by reflow soldering of the type used for surface-mounted components (SMCs).

FIG. 8 shows an integrated semiconductor circuit 5d etched directly on the rear face of the photovoltaic cell 4, in the material of the component, i.e. in poly-crystalline silicon. A semiconductor circuit 5d of adequate quality is initially integrated with each photovoltaic cell 4, thereby reducing the manufacturing operations that need to be performed on the photovoltaic module by eliminating a certain amount of soldering.

The invention makes it possible to reduce the costs of cabling the module, since 30% to 50% of the cabling can be omitted when using the invention. The space saved by omitting cabling enables the size of the module to be reduced. The invention also makes it possible to improve the dissipation of heat from the semiconductor circuits, and thus makes it possible to satisfy the requirements of the new IEC61215 Ed.2 standard.

The above-described embodiments of the present invention are intended to be examples only. Alterations, modifications and variations may be effected to the particular embodiments by those of skill in the art without departing from the scope of the invention, which is defined solely by the claims appended hereto.

What is claimed is:

1. A photovoltaic module comprising:
one or more photovoltaic cells connected in series and disposed inside a laminated stack of glass and polymer;
an electronic protection device arranged to bypass the electric current passing through at least one photovoltaic cell, the electronic protection device being a semiconductor circuit that is disposed inside the laminated stack; and
wherein the semiconductor circuit is electrically connected to the cells of the module via at least one flat metal ribbon disposed in the laminated stack in order to dissipate the heat energy given off by the semiconductor circuit.

2. The photovoltaic module according to claim 1, in which the semiconductor circuit is connected to the photovoltaic cells via two flat copper ribbons.

3. The photovoltaic module according to claim 1, in which the semiconductor circuit is an electronic chip soldered onto a photovoltaic cell.

4. The photovoltaic module according to claim 1, in which each photovoltaic cell is inserted between a glass plate and a polymer layer, the semiconductor protection circuit being disposed between a cell and the polymer layer.

5. The photovoltaic module according to claim 1, in which the semiconductor circuit is disposed between two adjacent photovoltaic cells.

6. The photovoltaic module according to claim 1, in which the semiconductor circuit comprises a poly-crystalline medium.

7. The photovoltaic module according to claim 1, in which the semiconductor circuit is mounted on a metal plate possessing good thermal conductivity, said plate serving as a radiator for dissipating heat energy.

8. The photovoltaic module according to claim 1, in which the semiconductor circuit is integrated in the photovoltaic cell.

9. The photovoltaic module according to claim 1, in which each photovoltaic cell is provided with a respective protective semiconductor circuit.

10. The photovoltaic module according to claim 1, further comprising monitoring and control circuits for the photovoltaic cells, and in which the monitoring and control circuits are semiconductor circuits disposed inside the laminated stack.

11. The photovoltaic module according to claim 10, in which the monitoring and control circuits are semiconductor circuits selected from the group consisting of thyristor, MOSFET, and GTO type semiconductor circuits.

12. The photovoltaic module according to claim 1, further comprising monitoring circuits for the photovoltaic cells, and in which the monitoring circuits are semiconductor circuits disposed inside the laminated stack.

13. The photovoltaic module according to claim 12, in which the monitoring circuits are semiconductor circuits selected from the group consisting of thyristor, MOSFET, and GTO type semiconductor circuits.

14. The photovoltaic module according to claim 1, further comprising control circuits for the photovoltaic cells, and in which the control circuits are semiconductor circuits disposed inside the laminated stack.

15. The photovoltaic module according to claim 14, in which the control circuits are semiconductor circuits selected from the group consisting of thyristor, MOSFET, and GTO type semiconductor circuits.

16. The photovoltaic module according to claim 1, wherein the electronic protection device is formed by a bypass diode.
